(19) United States
(12) Patent Application Publication
(10) Pub. No.: US 2005/0011068 A1
(43) Pub. Date: Jan. 20, 2005

(54) Semiconductor manufacturing apparatus, and method for manufacturing semiconductor device

(76) Inventor: Hideki Yuzawa, Iida-shi (JP)

Correspondence Address: HARNESS, DICKEY & PIERCE, P.L.C., P.O. BOX 828, BLOOMFIELD HILLS, MI, 48303, US

(21) Appl. No.: 10/863,820

(22) Filed: Jun. 8, 2004

(30) Foreign Application Priority Data
Jun. 9, 2003 (JP) 2003-163828

(51) Int. Cl. H01L 31/0203; B23P 19/00; H01L 21/44

(52) U.S. Cl. 29/740; 438/118

(57) ABSTRACT

A semiconductor manufacturing apparatus is provided. The apparatus comprises a bonding stage for holding a circuit substrate, a bonding head for disposing a semiconductor chip on the circuit substrate, and a transfer member transferring the circuit substrate. An extended section extends from the bonding stage on an upstream side of a transfer direction of the circuit substrate. A first heating controller controls heating of the bonding stage and the extended section. A second heating controller controls heating of the bonding head. The first heating controller controls heating of the extended section such that thermal expansion occurs in the circuit substrate in an amount corresponding to an amount of thermal expansion of a semiconductor chip that is heated by the bonding head.

### RELATED APPLICATIONS

This application claims priority to Japanese Patent Application No. 2003-163828 filed Jun. 9, 2003 which is hereby expressly incorporated by reference herein in its entirety.

### BACKGROUND

Technical Field of the Invention

The present invention relates to semiconductor manufacturing apparatuses and methods for manufacturing semiconductor devices, and in particular, is preferably applied to FDB (face down bonding) with COF (chip on film).

Conventional Technology

Concerning conventional semiconductor devices, for example, Japanese Laid-open Patent Application HEI 6-13148 describes a method for mounting a semiconductor chip on a flexible substrate by thermocompression bonding.

However, when a semiconductor chip is mounted on a flexible substrate by thermocompression bonding, thermal expansion occurs in the film substrate and the semiconductor chip. When the film substrate and the semiconductor chip have different thermal expansion amounts, and the semiconductor chip is bonded onto the film substrate, a problem occurs in that the accuracy in the bonding position deteriorates.

Accordingly, it is an object of the present invention to provide a semiconductor manufacturing apparatus and a method for manufacturing a semiconductor device, which can suppress deterioration of the accuracy in the bonding position due to thermal expansion.

### SUMMARY

To solve the aforementioned problem, a semiconductor manufacturing apparatus in accordance with an embodiment of the present invention is characterized in comprising: a bonding stage for holding a circuit substrate; a bonding head for disposing a semiconductor chip on the circuit substrate; transfer means for transferring the circuit substrate; an extended section extending from the bonding stage on an upstream side of a transfer direction of the circuit substrate; first heating control means for controlling heating of the bonding stage and the extended section; and second heating control means for controlling heating of the bonding head.

Accordingly, a circuit substrate can be pre-heated on an upstream side of the bonding stage, such that the circuit substrate can be thermally expanded in advance at the time of transferring the circuit substrate onto the bonding stage. For this reason, after the circuit substrate is thermally expanded in accordance with thermal expansion of the semiconductor chip, the semiconductor chip can be bonded to the circuit substrate, whereby the semiconductor chip can be accurately mounted on the circuit substrate.

Also, since the bonding stage is extended toward an upstream side of the transfer direction, a circuit substrate that is thermally expanded can be transferred onto the bonding stage without a gap. For this reason, even when a circuit substrate that is being transferred to the bonding stage stops during its transfer, the thermally expanded state of the circuit substrate that is being sent to the bonding stage can be maintained, and deterioration of the accuracy of the bonding position can be prevented.

Also, a semiconductor manufacturing apparatus in accordance with an embodiment of the present invention is characterized in that the first heating control means controls heating of the extended section such that thermal expansion occurs in the circuit substrate in an amount corresponding to the amount of thermal expansion of a semiconductor chip that is heated by the bonding head.

Consequently, thermal expansion can be generated in the circuit substrate in an amount corresponding to the amount of thermal expansion of the semiconductor chip; and even when the semiconductor chip is to be bonded to the circuit substrate while heating the semiconductor chip through the bonding head, the semiconductor chip can be accurately mounted on the circuit substrate.

Also, a semiconductor manufacturing apparatus in accordance with an embodiment of the present invention is characterized in comprising: a bonding stage for holding a circuit substrate; a bonding head for disposing a semiconductor chip on the circuit substrate; a transfer means for transferring the circuit substrate; a pre-heating means for preheating a circuit substrate that is sent to the bonding stage; a first heating control means for controlling heating of the bonding stage; and a second heating control means for controlling heating of the bonding head.

Accordingly, a circuit substrate can be preheated before bonding of a semiconductor chip is conducted, such that the circuit substrate can be thermally expanded in advance at the time of transferring the circuit substrate onto the bonding stage. For this reason, even when the times of retaining circuit substrates on the bonding stage are different from one another, the circuit substrates can be thermally expanded according to the thermal expansions of semiconductor chips, and then the semiconductor chips can be bonded on the circuit substrates, such that the semiconductor chips can be accurately mounted on the circuit substrates even when the circuit substrates have different product pitches.

Also, a method for manufacturing a semiconductor device in accordance with an embodiment of the present invention is characterized in comprising thermally expanding a circuit substrate according to a thermal expansion amount of a semiconductor chip, and then mounting the semiconductor chip on the circuit substrate.

Accordingly, even when a semiconductor chip is heated at the time of mounting the semiconductor chip on a circuit substrate, the circuit substrate can be thermally expanded in an amount corresponding to the amount of thermal expansion of the semiconductor chip, such that the semiconductor chip can be accurately mounted on the circuit substrate.

Also, a method for manufacturing a semiconductor device in accordance with an embodiment of the present invention is characterized in comprising: a step of preheating a circuit substrate; a step of transferring the circuit substrate pre-heated to a bonding stage; and a step of bonding a semiconductor chip on the circuit substrate transferred onto the bonding stage.

Consequently, a circuit substrate can be pre-heated before a semiconductor chip is bonded, and then the circuit substrate can be transferred onto the bonding stage, such that the circuit substrate can be thermally expanded in advance at the time of transferring the circuit substrate onto the bonding stage. For this reason, the circuit substrate can be thermally expanded in accordance with thermal expansion of the semiconductor chip, and then the semiconductor chip can be bonded onto the circuit substrate, such that the semiconductor chip can be accurately mounted on the circuit substrate even when the semiconductor chip is heated at the time of mounting the semiconductor chip on the circuit substrate.

Also, a method for manufacturing a semiconductor device in accordance with an embodiment of the present invention is characterized in comprising: a step of transferring a circuit substrate onto a heat block whose temperature is set to generate thermal expansion in the circuit substrate in an amount corresponding to the amount of thermal expansion of a semiconductor chip; a step of transferring the circuit substrate that has been transferred onto the heat block onto a bonding stage; and a step of bonding the semiconductor chip to the circuit substrate that has been transferred onto the bonding stage.

Accordingly, while bonding of a semiconductor chip is conducted on the downstream side of a circuit substrate, the circuit substrate can be thermally expanded according to the amount of thermal expansion of a semiconductor chip on the upstream side of the circuit substrate. For this reason, without considering the transfer tact for semiconductor chips on the bonding stage, the amount of thermal expansion of semiconductor chips can be matched with the amount of thermal expansion of the circuit substrate, deterioration of the transfer efficiency can be suppressed, and the semiconductor chips can be accurately mounted on the circuit substrate.

Also, a method for manufacturing a semiconductor device in accordance with an embodiment of the present invention is characterized in that the heat block is formed in one piece with the bonding stage on an upstream side thereof.

Consequently, a circuit substrate that is thermally expanded by the heat block can be transferred onto the bonding stage without a gap. For this reason, even when a circuit substrate that is being transferred to the bonding stage stops during its transfer, the thermally expanded state of the circuit substrate that is being sent to the bonding stage can be maintained, and deterioration of the accuracy in the bonding position can be prevented.

### BRIEF DESCRIPTION OF THE DRAWINGS

FIGS. 1(a)-(c) are cross-sectional views indicating a bonding method in accordance with a first embodiment of the present invention.

FIGS. 2(a)-(c) are cross-sectional views indicating a bonding method in accordance with a second embodiment of the present invention.

### DETAILED DESCRIPTION

A bonding apparatus and a bonding method in accordance with embodiments of the present invention will be described below with reference to the accompanying drawings.

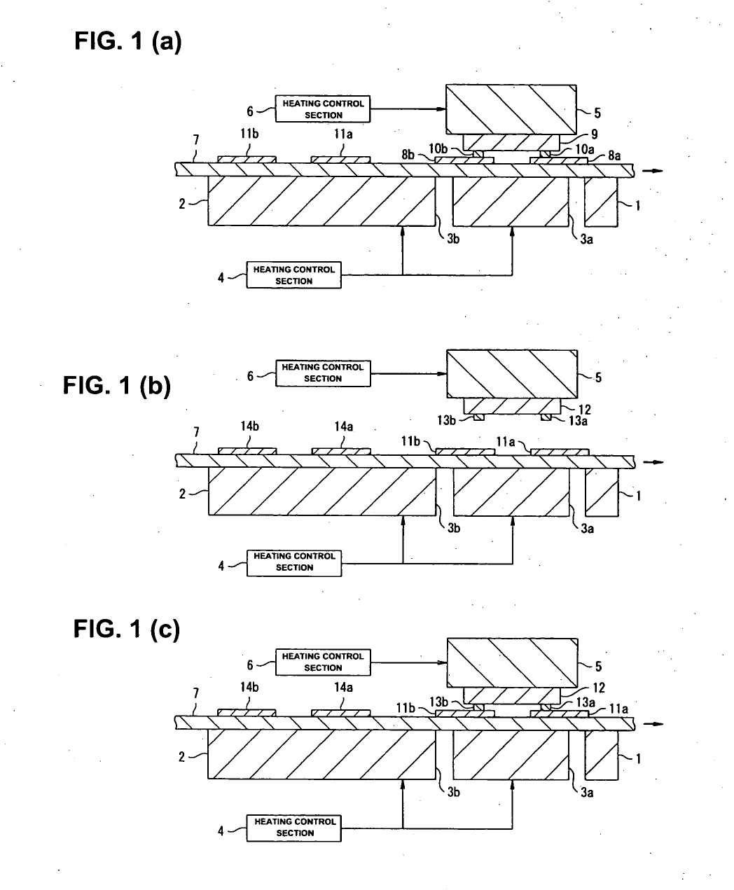

FIGS. 1(a)-(c) a show cross-sectional views indicating a bonding method in accordance with a first embodiment of the present invention.

In FIGS. 1(a)-(c) a, a bonding stage 1 is provided with suction holes 3a and 3b for applying suction to a tape substrate 7, and an extended section 2 that extends from the bonding stage 1 is provided on an upstream side of a transfer direction of the tape substrate 7. Also, a bonding head 5 is provided above the bonding stage 1 that holds a semiconductor chip 9, 12 by suction and disposes the semiconductor chip 9, 12 on the tape substrate 7.

It is noted here that the semiconductor chips 9 and 12 are provided with protruded electrodes 10a and 10b, and 13a and 13b, respectively; and the tape substrate 7 is provided with lead electrodes 8a, 8b, 11a, 11b, 14a and 14b formed thereon.

Also, the bonding apparatus is provided with a heating control section 4 for controlling heating of the bonding stage 1 and the extended section 2, and a heating control section 6 for controlling heating of the bonding head 5.

It is assumed here that the lead electrodes 8a and 8b are formed in a circuit block on the tape substrate 7 which is subject to bonding this time, the lead electrodes 11a and 11b are formed in a circuit block on the tape substrate 7 which is subject to bonding next, and the lead electrodes 14a and 14b are formed in a circuit block on the tape substrate 7 which is subject to bonding the time after next.

As indicated in FIG. 1(a), a forming region of the lead electrodes 8a and 8b that are subject to bonding this time is transferred onto the bonding stage 1, and a forming region of the lead electrodes 11a and 11b that are subject to bonding next is transferred onto the extended section 2. Then, while applying suction to the tape substrate 7 through the suction holes 3a and 3b, the semiconductor chip 9 that is held by suction from the bonding head 5 is disposed over the forming region of the lead electrodes 8a and 8b that are to be bonded this time, and the protruded electrodes 10a and 10b provided on the semiconductor chip 9 are bonded to the lead electrodes 8a and 8b.

It is noted here that the semiconductor chip 9 that is held by suction from the bonding head 5 is heated through the bonding head 5. Also, the forming region of the lead electrodes 8a and 8b transferred onto the bonding stage 1 is heated through the bonding stage 1, and the forming region of the lead electrodes 11a and 11b transferred onto the extended section 2 of the bonding stage 1 is heated through the extended section 2 of the bonding stage 1.

It is noted here that the temperature of the bonding stage 1 and the extended section 2 can be set such that thermal expansion occurs in the tape substrate 7 in an amount corresponding to the amount of thermal expansion of the semiconductor chip 9 that is heated by the bonding head 5. For example, the bonding head 5 can be set to a temperature of about 465° C., and the bonding stage 1 and the extended section 2 can be set to a temperature of about 115±15° C.

Then, after the protruded electrodes 10a and 10b provided on the semiconductor chip 9 are bonded to the lead electrodes 8a and 8b, the tape substrate 7 is transferred. Then, as indicated in FIG. 1(b), the forming region of the lead electrodes 11a and 11b that are to be bonded this time is transferred onto the bonding stage 1, and the forming region of the lead electrodes 14a and 14b that are to be bonded next is transferred onto the extended section 2.

Then, as indicated in FIG. 1(c), while applying suction to the tape substrate 7 through the suction holes 3a and 3b, the semiconductor chip 12 that is held by suction from the bonding head 5 is disposed over the forming region of the lead electrodes 11a and 11b that are to be bonded this time, and the protruded electrodes 13a and 13b provided on the semiconductor chip 12 are bonded to the lead electrodes 11a and 11b.

It is noted here that the forming region of the lead electrodes 11a and 11b that are to be bonded this time is heated by the extended section 2 before being transferred onto the bonding stage 1. Therefore, the forming region of the lead electrodes 11a and 11b can be transferred onto to the bonding stage 1 after thermal expansion is generated in advance in the forming region of the lead electrodes 11a and 11b in an amount corresponding to the amount of thermal expansion of the semiconductor chip 12. For this reason, without depending on the time in which the forming region of the lead electrodes 11a and 11b stays on the bonding stage 1, the semiconductor chip 12 can be bonded to the tape substrate 7 in a state in which the forming region of the lead electrodes 11a and 11b is thermally expanded in an amount corresponding to the thermal expansion of the semiconductor chip 12, and therefore the semiconductor chip 12 can be accurately mounted on the tape substrate 7.

Also, through extending the bonding stage 1 to the upstream side of the transfer direction of the tape substrate 7, the tape substrate 7 that is thermally expanded can be transferred onto the bonding stage 1 without a gap. For this reason, even when the tape substrate 7 stops during its transfer due to occurrence of trouble, the tape substrate 7 that is to be sent to the bonding stage 1 can maintain its thermally expanded state, and therefore deterioration of the accuracy in the bonding position can be prevented.

It is noted that, as the protruded electrodes 10a, 10b, 13a and 13b, for example, Au bumps, Au/Ni bumps, Cu bumps or Ni bumps coated with solder material, solder balls or the like can be used. Also, as the lead electrodes 8a, 8b, 11a and 11b, for example, copper (Cu), iron (Fe), gold (Au), silver (Ag), copper (Cu) coated with solder material, copper (Cu) coated with gold (Au) or the like can be used.

Also, for connecting the protruded electrodes 10, 10b, 13a and 13b to the lead electrodes 8a, 8b, 11a and 11b, for example, metal bonding such as solder bonding or alloy bonding may be used, or another pressure bonding such as ACF (Anisotropic Conductive Film) bonding, NCF (Nonconductive Film) bonding, ACP (Anisotropic Conductive Paste) bonding, NCP (Nonconductive Paste) bonding or the like may be used. Also, in the embodiment described above, the description is made, using a COF (chip on film) as an example. However, the present invention may be applied to TCP (tape carrier package), COG (chip on glass) and TCM (tape carrier module).

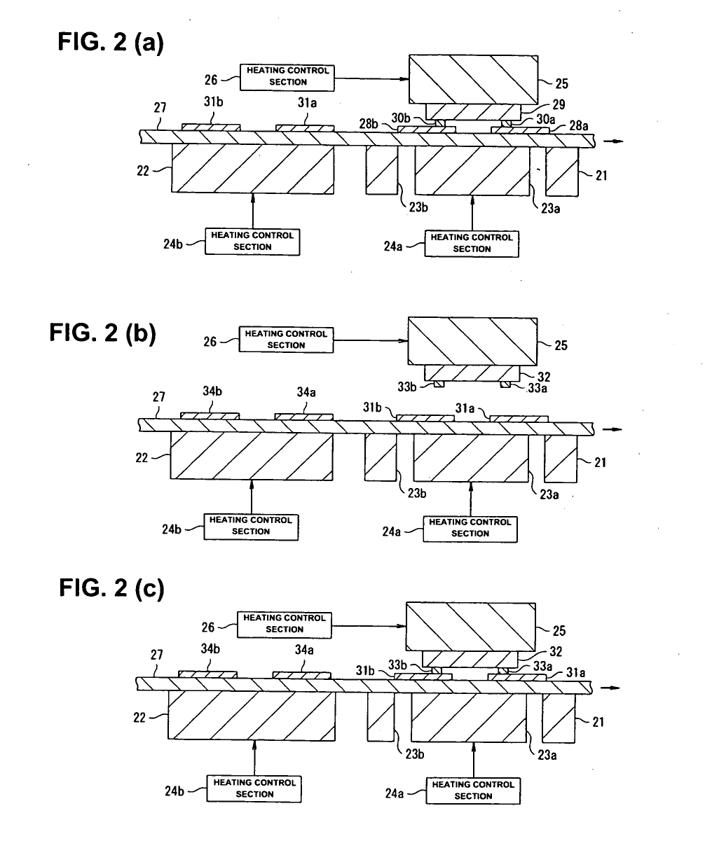

FIGS. 2(a)-(c) a show cross-sectional views indicating a bonding method in accordance with a second embodiment of the present invention.

In FIGS. 2(a)-(c) a, a bonding stage 21 is provided with suction holes 23a and 23b for applying suction to a tape substrate 27, and a heat block 22 for preheating the tape substrate 27 is provided on an upstream side of a transfer direction of the tape substrate 27. Also, a bonding head 25 is provided above the bonding stage 21 that holds a semiconductor chip 29, 32 by suction and disposes the semiconductor chip 29, 32 on the tape substrate 27.

It is noted here that the semiconductor chips 29 and 32 are provided with protruded electrodes 30a and 30b, and 33a and 33b, respectively; and the tape substrate 27 is provided with lead electrodes 28a, 28b, 31a, 31b, 34a and 34b formed thereon.

Also, the bonding apparatus is provided with heating control sections 24a and 24b for controlling heating of the bonding stage 21 and the heat block 22, respectively, and a heating control section 26 for controlling heating of the bonding head 25.

It is assumed here that the lead electrodes 28a and 28b are formed in a circuit block on the tape substrate 27 which is subject to bonding this time, the lead electrodes 31a and 31b are formed in a circuit block on the tape substrate 27 which is subject to bonding next, and the lead electrodes 34a and 34b are formed in a circuit block on the tape substrate 27 which is subject to bonding the time after next.

As indicated in FIG. 2(a), a forming region of the lead electrodes 28a and 28b that are bonded this time is transferred onto the bonding stage 21, and a forming region of the lead electrodes 31a and 31b that are bonded next is transferred onto the heat block 22. Then, while applying suction to the tape substrate 27 through the suction holes 23a and 23b, the semiconductor chip 29 that is held by suction from the bonding head 25 is disposed over the forming region of the lead electrodes 28a and 28b that are to be bonded this time, and the protruded electrodes 30a and 30b provided on the semiconductor chip 29 are bonded to the lead electrodes 28a and 28b.

It is noted here that the semiconductor chip 29 that is held by suction from the bonding head 25 is heated through the bonding head 25. Also, the forming region of the lead electrodes 28a and 28b transferred onto the bonding stage 21 is heated through the bonding stage 21, and the forming region of the lead electrodes 31a and 31b transferred onto the heat block 22 is heated through the heat block 22.

It is noted here that the temperature of the bonding stage 21 and the heat block 22 can be set such that thermal expansion occurs in the tape substrate 27 in an amount corresponding to the amount of thermal expansion of the semiconductor chip 29 that is heated by the bonding head 25. For example, the bonding head 25 can be set to a temperature of about 465° C., and the bonding stage 21 and the heat block 22 can be set to a temperature of about 115±15° C.

Then, after the protruded electrodes 30a and 30b provided on the semiconductor chip 29 are bonded to the lead electrodes 28a and 28b, the tape substrate 27 is transferred. Then, as indicated in FIG. 2(b), the forming region of the lead electrodes 31a and 31b that are to be bonded this time is transferred onto the bonding stage 21, and the forming region of the lead electrodes 34a and 34b that are to be bonded next is transferred onto the heat block 22.

Then, as indicated in FIG. 2(c), while applying suction to the tape substrate 27 through the suction holes 23a and 23b, the semiconductor chip 32 that is held by suction from the bonding head 25 is disposed over the forming region of the lead electrodes 31a and 31b that are to be bonded this time, and the protruded electrodes 33a and 33b provided on the semiconductor chip 32 are bonded to the lead electrodes 31a and 31b.

It is noted here that the forming region of the lead electrodes 31a and 31b that are to be bonded this time is heated by the heat block 22 before being transferred onto the bonding stage 21. Therefore, the forming region of the lead electrodes 31a and 31b can be transferred onto the bonding stage 21 after thermal expansion is generated in advance in the forming region of the lead electrodes 31a and 31b in an amount corresponding to the amount of thermal expansion of the semiconductor chip 32. For this reason, without depending on the time in which the forming region of the lead electrodes 31a and 31b stays on the bonding stage 21, the semiconductor chip 32 can be bonded to the tape substrate 27 in a state in which the forming region of the lead electrodes 31a and 31b is thermally expanded in an amount corresponding to the thermal expansion of the semiconductor chip 32.

As a result, even when product pitches in the tape substrate 27 are different from one another, the semiconductor chip 32 can be accurately mounted on the tape substrate 27. Also, by providing the heat block 22 on the upstream side of the bonding stage 21, the forming region of the lead electrodes 31a and 31b can be thermally expanded in an amount corresponding to thermal expansion of the semiconductor chip 32 without having to modify the bonding stage 21, and thus the semiconductor chip 32 can be accurately mounted on the tape substrate 27 without increasing the cost of the bonding stage 21.

It is noted that the heat block 22 may be disposed so as to contact the bonding stage 21. By so doing, the tape substrate 27 that is thermally expanded by the heat block 22 can be transferred onto the bonding stage 21 without a gap. For this reason, even when the tape substrate 27 stops during its transfer due to occurrence of trouble, the thermally expanded state of the tape substrate 27 that is to be transferred to the bonding stage 21 can be maintained, and deterioration of the accuracy in the bonding position can be prevented.

The description of the invention is merely exemplary in nature and, thus, variations that do not depart from the gist of the invention are intended to be within the scope of the invention. Such variations are not to be regarded as a departure from the spirit and scope of the invention.

1. A semiconductor manufacturing apparatus comprising:
a bonding stage for holding a circuit substrate;
a bonding head for disposing a semiconductor chip on the circuit substrate;
a transfer member transferring the circuit substrate;
an extended section extending from the bonding stage on an upstream side of a transfer direction of the circuit substrate;
a first heating controller controlling heating of the bonding stage and the extended section; and
a second heating controller controlling heating of the bonding head.

2. The semiconductor manufacturing apparatus of claim 1, wherein the first heating controller controls heating of the extended section such that thermal expansion occurs in the circuit substrate in an amount corresponding to an amount of thermal expansion of a semiconductor chip that is heated by the bonding head.

3. A semiconductor manufacturing apparatus comprising:
a bonding stage for holding a circuit substrate;
a bonding head for disposing a semiconductor chip on the circuit substrate;
a transfer member transferring the circuit substrate;
a pre-heater preheating a circuit substrate that is sent to the bonding stage;
a first heating controller controlling heating of the bonding stage; and
a second heating controller controlling heating of the bonding head.

4. A method for manufacturing a semiconductor device comprising:
thermally expanding a circuit substrate in an amount corresponding to an amount of thermal expansion of a semiconductor chip; and
thereafter, mounting the semiconductor chip on the circuit substrate.

5. A method for manufacturing a semiconductor device comprising:
a step of preheating a circuit substrate;
a step of transferring the pre-heated circuit substrate to a bonding stage; and
a step of bonding a semiconductor chip on the circuit substrate transferred onto the bonding stage.

6. A method for manufacturing a semiconductor device comprising:
a step of transferring a circuit substrate onto a heat block having a temperature that is set to generate thermal expansion in the circuit substrate in an amount corresponding to an amount of thermal expansion of a semiconductor chip;
a step of transferring the circuit substrate that has been transferred onto the heat block onto a bonding stage; and
a step of bonding the semiconductor chip to the circuit substrate that has been transferred to the bonding stage.

7. A method for manufacturing a semiconductor device according to claim 6, wherein the heat block is formed in one piece with the bonding stage on an upstream side thereof.
